(19) United States
(12) Patent Application Publication
(10) Pub. No.: US 2011/0190083 A1
(43) Pub. Date: Aug. 4, 2011

(54) ACCESSORY DRIVE SYSTEM FOR A VEHICLE

(75) Inventors: Albert W. Harrison, III, Detroit, MI (US); John D. Thomas, Rochester, MI (US); William Jeff DeFrank, Livonia, MI (US); Nam-Huan Thai-Tang, Bloomfield, MI (US)

(73) Assignee: ALTe, Auburn Hills, MI (US)

(21) Appl. No.: 13/018,875

(22) Filed: Feb. 1, 2011

Related U.S. Application Data
(60) Provisional application No. 61/300,621, filed on Feb. 2, 2010.

(51) Int. Cl. F16H 7/08; F16H 7/02; H05K 13/00

(52) U.S. Cl. 474/101; 474/150; 29/592.1

(57) ABSTRACT

An accessory drive system for a vehicle comprises an electric motor adapted for receiving power from a battery and a least one accessory component for the vehicle. A serpentine belt is connected the motor and to the at least one accessory component such that the motor drives the at least one accessory component. A frame supports the electric motor and the at least one accessory component.

### CROSS REFERENCE TO RELATED APPLICATIONS

This application claims the benefit of U.S. Provisional Application Ser. No. 61/300,621 filed Feb. 2, 2010, the entire contents of which are hereby incorporated by reference.

### TECHNICAL FIELD

The present invention relates to an arrangement and method for driving accessory components in a vehicle.

### BACKGROUND

Advancements in technology and the growing concern for environmentally efficient vehicles have led to the use of alternative fuel and power sources in vehicles. Electric vehicles or hybrid electric vehicles use electric motors and energy storage systems (ESS) to provide power for various vehicle requirements. The motor and ESS must provide the power to drive the vehicle as well as to operate various accessory systems within the vehicle, such as heating/cooling systems, power steering systems, etc. However, powering the various accessory drive systems uses power that may otherwise drive the vehicle or extend the range of the vehicle. Additionally, in order to efficiently provide power for the vehicle, the motor may only operate when the vehicle is in motion. However, the accessory systems, like the air conditioning system, may require power when the vehicle is not in motion.

### SUMMARY

An accessory drive system for a vehicle comprises an electric motor adapted for receiving power from a battery ,and a least one accessory component for the vehicle. A serpentine belt is connected to the motor and to the at least one accessory component such that the motor drives the at least one accessory component. A frame supports the electric motor and the at least one accessory component.

A vehicle comprises a first battery adapted to provide at least a portion of driving power for the vehicle, and an accessory drive system. The accessory drive system includes an accessory motor and at least one accessory component. A serpentine belt connects the electric motor to the at least one accessory component such that the accessory motor drives the at least one accessory component. A second battery is configured to provide power to the electric motor. The second battery is electrically independent from the first battery.

A method of driving an accessory component in a vehicle comprises providing at least a portion of the driving power for the vehicle with a first battery and powering an second motor with a second battery. A serpentine belt is rotated about a plurality of pulleys with the motor. At least one accessory component is driven with the rotation of at least one of the plurality of pulleys such that the accessory motor drives the at least one accessory component. The at least one accessory component and the second motor are mounted to a frame to form a modular assembly which is supported by the vehicle.

The above features and advantages, and other features and advantages of the present invention will be readily apparent from the following detailed description of the preferred embodiments and best modes for carrying out the present invention when taken in connection with the accompanying drawings and appended claims.

### BRIEF DESCRIPTION OF THE DRAWINGS

FIG. 1 is a schematic plan view illustration of an electric vehicle having an accessory drive system;

FIG. 2A is a schematic perspective front view illustration of a first embodiment of an accessory drive for the vehicle of FIG. 1;

FIG. 2B is a schematic perspective rear view illustration of the first embodiment of the accessory drive for the vehicle of FIGS. 1-2A;

FIG. 3 is a schematic perspective exploded view of the first embodiment of the accessory drive for the vehicle of FIGS. 1-2B;

FIG. 4A is a schematic perspective view of a first modular assembly for a frame for the first embodiment of the accessory drive for the vehicle of FIGS. 1-3;

FIG. 4B is a schematic perspective view of a second modular assembly for the frame for the first embodiment of the accessory drive for the vehicle of FIGS. 1-3;

FIG. 4C is a schematic perspective view of a third modular assembly for the frame for the first embodiment of the accessory drive for the vehicle of FIGS. 1-3;

FIG. 4D is a schematic perspective view of a fourth modular assembly for the frame for the first embodiment of the accessory drive for the vehicle of FIGS. 1-3;

FIG. 4E is a schematic perspective view of a fifth modular assembly for the frame for the first embodiment of the accessory drive for the vehicle of FIGS. 1-3;

FIG. 4F is a schematic perspective view of a sixth modular assembly for the frame for the first embodiment of the accessory drive for the vehicle of FIGS. 1-3;

FIG. 5A is a side schematic illustration of the accessory drive system of FIGS. 1-3 in a first position within the vehicle of FIG. 1;

FIG. 5B is a side schematic illustration of the accessory drive system of FIGS. 1-3 in a second position within the vehicle of FIG. 1;

FIG. 5C is a side schematic illustration of the accessory drive system of FIGS. 1-3 in a third position within the vehicle of FIG. 1; and

FIG. 6 is an exploded perspective schematic illustration of accessibility during maintenance of the accessory drive system for the vehicle of FIGS. 1-3.

### DESCRIPTION OF THE PREFERRED EMBODIMENTS

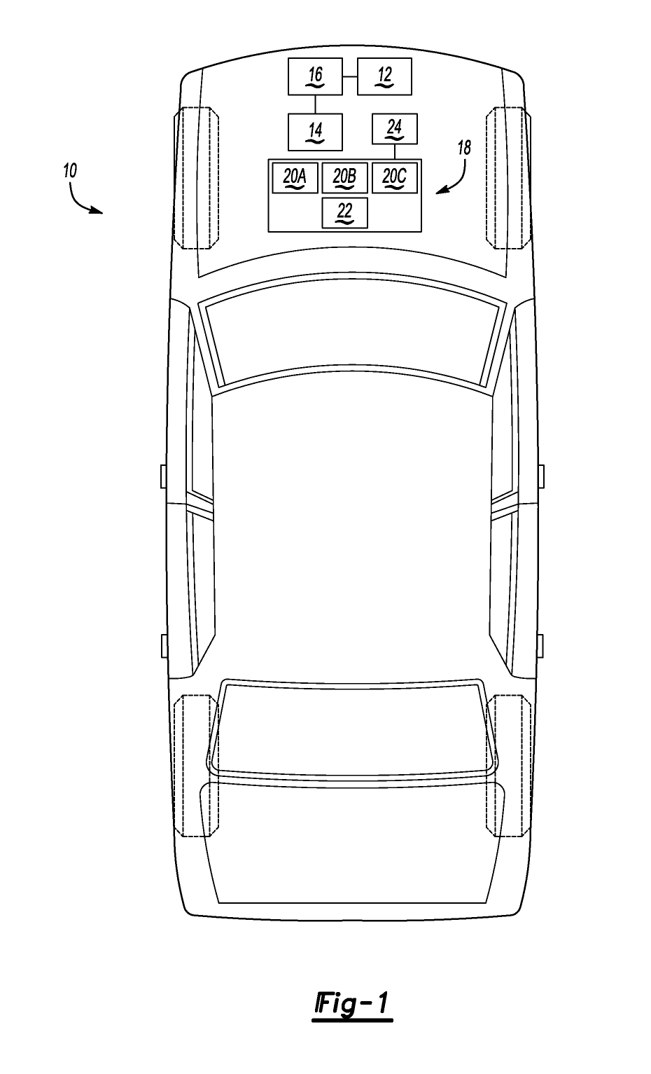

Referring to the Figures, wherein like reference numbers refer to the same or similar components throughout the several views, FIG. 1 schematically illustrates a vehicle 10 including at least one motor 12, a transmission or gear drive 14, and an energy storage system (ESS) 16. The at least one motor 12 may be a motor/generator and the ESS 16 may provide power to drive the motor 12 or store power generated by the motor 12 as the vehicle 10 operates. An inverter (not shown) may be connected between the motor 12 and the ESS 16.

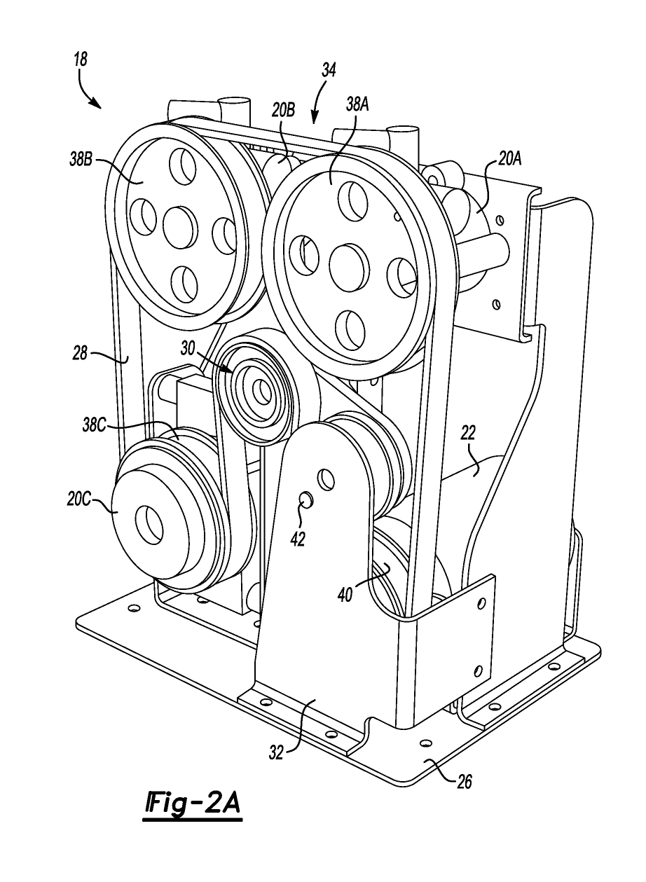

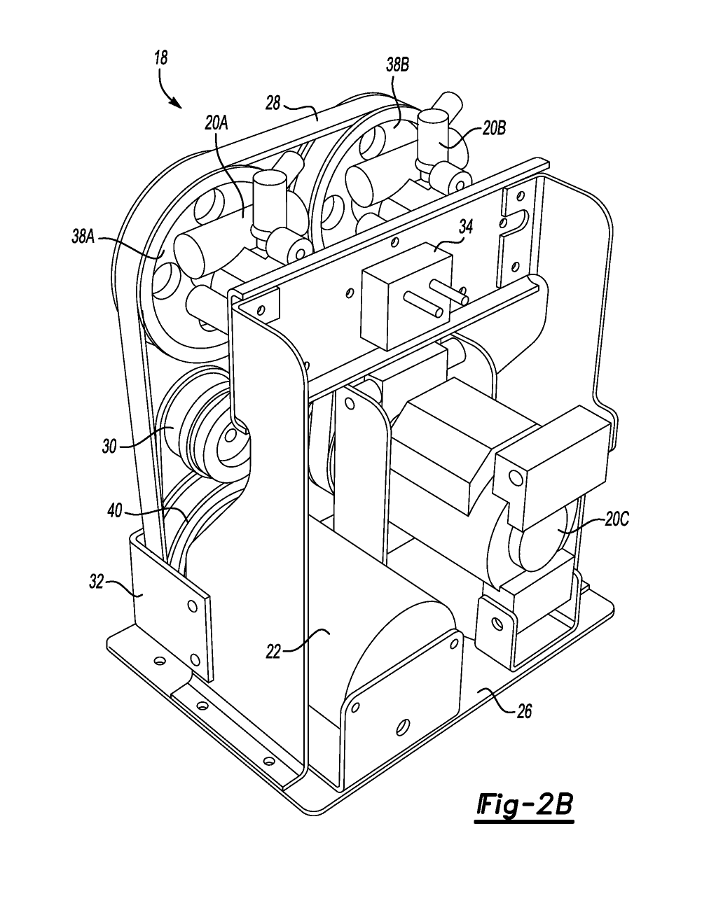

An accessory drive system 18 is also supported by the vehicle 10. The accessory drive system 18 includes at least one accessory component 20A. In the embodiment shown in FIGS. 2A-6 the accessory drive system 18 includes a first accessory component 20A, a second accessory component 20B, and a third accessory component 20C. In the embodiment shown, the three accessory components 20A-C are a power steering pump, an air conditioning compressor, and an emissions control pump. However, the accessory drive system 18 may include other accessory components, and fewer or additional accessory components 20A-C as is desired for a particular vehicle 10 configuration. The accessory components 20A-C are not required to be the same size as one another, as the accessory drive system 18 can be adapted to different size accessories and differing numbers of accessories as explained in further detail below.

The accessory drive system 18 also includes an accessory motor 22. The accessory motor 22 is an electric motor and is separate from the motor 12 which drives the vehicle 10. An accessory battery 24 may be connected to the accessory motor 22 to provide power to the accessory motor 22. The accessory battery 24 is preferably a 12 Volt DC battery, which is separate from the ESS 16 that is used to store and provide power to the main motor 12 for the vehicle 10. That is, the accessory battery 24 is electrically independent from the ESS 16 and may be separately electrically charged and controlled from the ESS 16. Additionally, the accessory battery 24 is most likely electrically connected for providing power to different vehicle 10 components than the ESS 16. However, the accessory battery 24 may be utilized by various systems for the vehicle 10 in addition to the accessory drive system 18. For example, the accessory battery 24 may power the vehicle radio, power windows, etc. The accessory battery 24 may be remote from and electrically connected to the accessory drive system 18. Additional components for charging the battery may also be located on the vehicle 10 remote from the accessory drive system 18. Preferably, the accessory battery 24 and associated components are part of the vehicle 10 and are not required to be added in order to operate the accessory drive system 18.

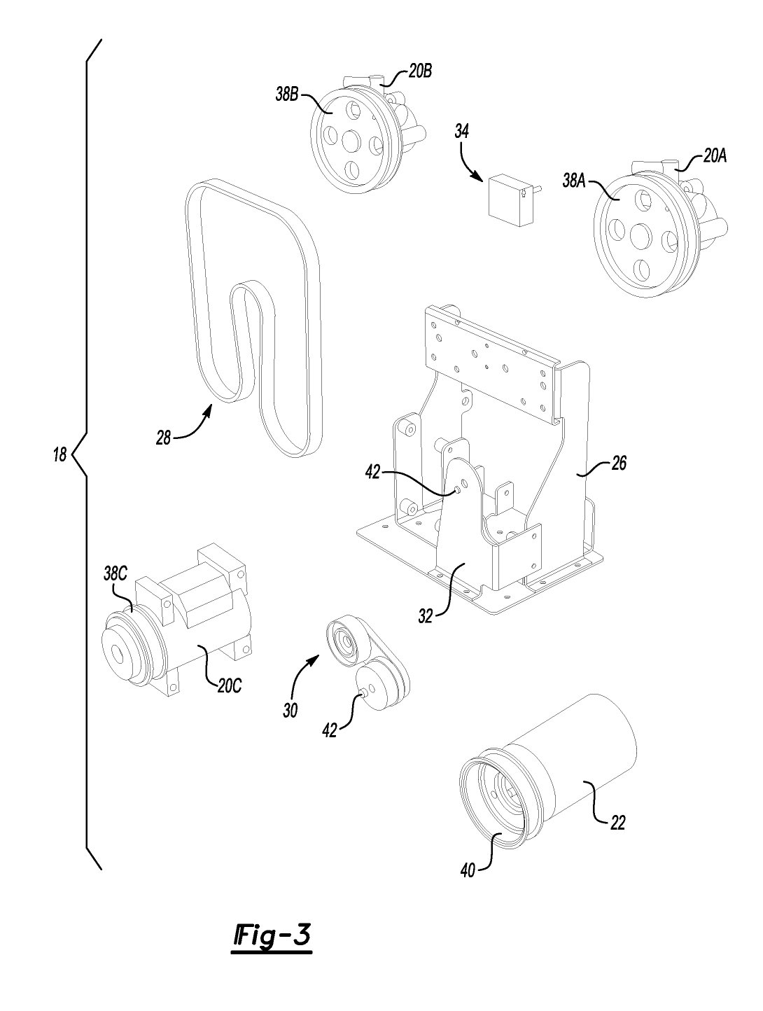

Referring to FIGS. 2A-3 the accessory drive system 18 is described in further detail. The accessory drive system 18 includes a frame 26 for supporting the accessory components 20A-C. The accessory motor 22 drives a serpentine belt 28 which in turn drives the accessory components 20A-C. The serpentine belt 28 may include multiple grooves to enhance contact between the serpentine belt 28, the accessory motor 22, and the accessory components 20A-C.

A belt tensioner 30 is used to maintain tension on the serpentine belt 28 for operation of the accessory drive system 18. A belt tensioner bracket 32 may be secured to the frame 26 for supporting the belt tensioner 30. The belt tensioner 30 and the belt tensioner bracket 32 may also incorporate an anti-rotation feature 42. The anti-rotation feature 42 prevents rotation of the belt tensioner 30 relative to the belt tensioner bracket 32 and maintains the proper pressure on the serpentine belt 28. In the embodiment shown, the anti-rotation feature 42 is a mating tab and slot on the belt tensioner 30 and the belt tensioner bracket 32. The belt tensioner bracket 32 is removably attached to the frame 26 in a manner that allows the belt tensioner bracket 32 to be removed for service of the accessory drive system 18, as described in further detail below.

Each of the accessory components 20A-C includes a pulley 38A-C. Likewise, the accessory motor 22 includes a pulley 40. The serpentine belt 28 is wrapped around the pulleys 38A-C and 40 such that the accessory motor 22 drives the serpentine belt 28 through motor pulley 40, which in turn rotates the pulleys 38A-C for each of the accessory components 20A-C. In order to vary the input speed to the accessory components 20A-C, the pulleys 38A-C may have varying diameters from one another. One skilled in the art would be able to determine the appropriate pulley 38A-C size relative to the associated accessory component 20A-C for a particular accessory drive system 18.

As mentioned above, the accessory components 20A-C may be of varying sizes and mounted on the frame 26 in varying locations. The size of the accessory components 20A-C and the mounting locations of the accessory components 20A-C on the frame 26 should be arranged to maintain each accessory pulley 38A-C and motor pulley 40 in a common plane to reduce wear and assist performance of the serpentine belt 28. Additional pulleys (not shown) may also be rotatably mounted to the frame 26 to maintain tension of the serpentine belt 28, depending on the number and the configuration of the accessory components 20A-C. One skilled in the art would be able to determine the number and placement of additional pulleys based upon the number and arrangement of the accessory components 20A-C.

Additionally, although not shown, clutches may be associated with each of the accessory components 20A-C and located between the accessory component 20A-C and the associated pulley 38A-C. The clutches may allow the accessory component 20A-C to be temporarily disengaged from the accessory drive system 18 while allowing the serpentine belt 28 to rotate and drive the other accessory drive components 20A-C that remain engaged. Therefore, disengaging one of the accessory components 20A-C through a clutch temporarily reduces load on the accessory motor 22 when the accessory drive system 18 is operating and a particular accessory component 20A-C is not required.

A controller 34 is mounted to the frame 26 and electrically connected (not shown) to the accessory motor 22. The controller 34 may switch the accessory motor 22 between on and off positions to control operation of the accessory drive system 18 and to regulate the power output to the accessory components 20A-C. The controller 34 and the accessory drive system 18 allow for operation of the accessory components 20A-C independent of the operation of the main motor 12 and the transmission 14. Independent operation of the accessory components 20A-C may be especially important in electric vehicles 10, because the main motor 12 may be turned off to save energy even when the vehicle 10 is operating and requires use of the accessory drive components 20A-C.

The controller 34 may also provide additional input to the accessory motor 22 for controlling the accessory drive system 18. For example, the controller 34 may limit or control speed of the accessory motor 22 to control the speed of the belt 28 and the accessory components 20A-C. The complexity of the controller 34 and operation of the accessory drive system 18 may depend on the particular vehicle 10 application which the accessory drive system 18 is intended for use with. Alternatively, the controller 34 may be turned on/off of the accessory motor 22 based upon selected information or a signal from the vehicle 10 electronic control unit (not shown). For example, the controller 34 may turn the accessory motor 22 on at a predetermined ambient temperature, such that an accessory component 20A-C associated with a vehicle heating or cooling system may be turned on to cool/heat the vehicle. Therefore, the controller 34 selectively powers the accessory motor 22 based upon a predetermined condition of the at least one component 20A-C. One skilled in the art would be able to determine the type or controller 34 and control conditions required for a particular accessory drive system 18.

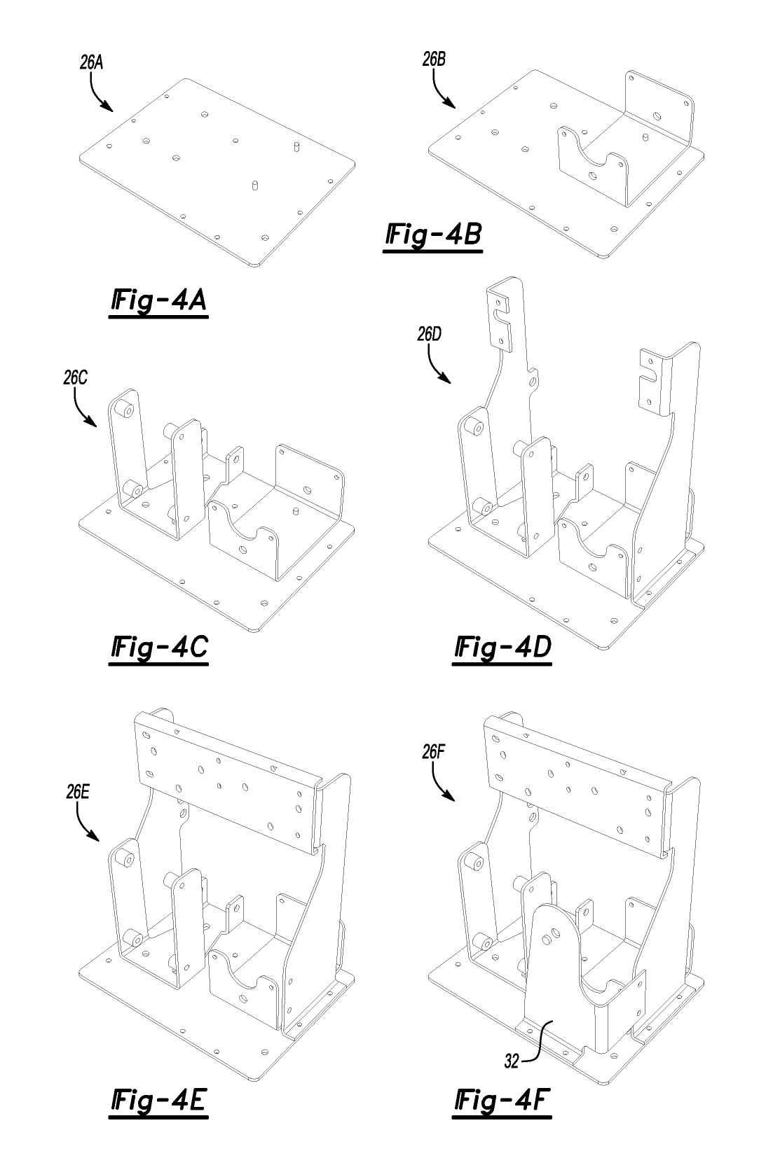

As can be seen by viewing FIGS. 4A-4F, the frame 26A-F is a modular assembly that will allow for additional accessory components 20A-C to be added or removed. For example, the frame 26A-F may include various brackets for supporting the accessory components 20A-C (shown in FIG. 2A). The component brackets (not numbered) may assist in supporting the individual components 20A-C, while allowing each component 20A-C to be independently removed from the frame 26A-F for servicing. In particular, the belt tensioner bracket 32 may be a modular component to allow for service of the accessory drive system 18.

Referring again to FIGS. 2A-3, the frame 26 must be able to support the weight of the motor 22, and the accessory drive components 20A-C. The frame 26 must also be able to withstand the torque placed on the accessory drive components 26A-C by the belt 28 and the belt tensioner 30. Although FIGS. 4A-F illustrate several modular configurations of the frame 26 the frame 26 may be a single piece, such as a molded or die-cast plastic. Different configurations for the frame 26 and the accessory drive components 26A-C may also be utilized depending on the number of accessory drive components 20A-C and the packaging available within the vehicle 10. One skilled in the art would be able to determine the appropriate arrangement of the accessory drive components 20A-C and the frame 26 for a particular vehicle 10.

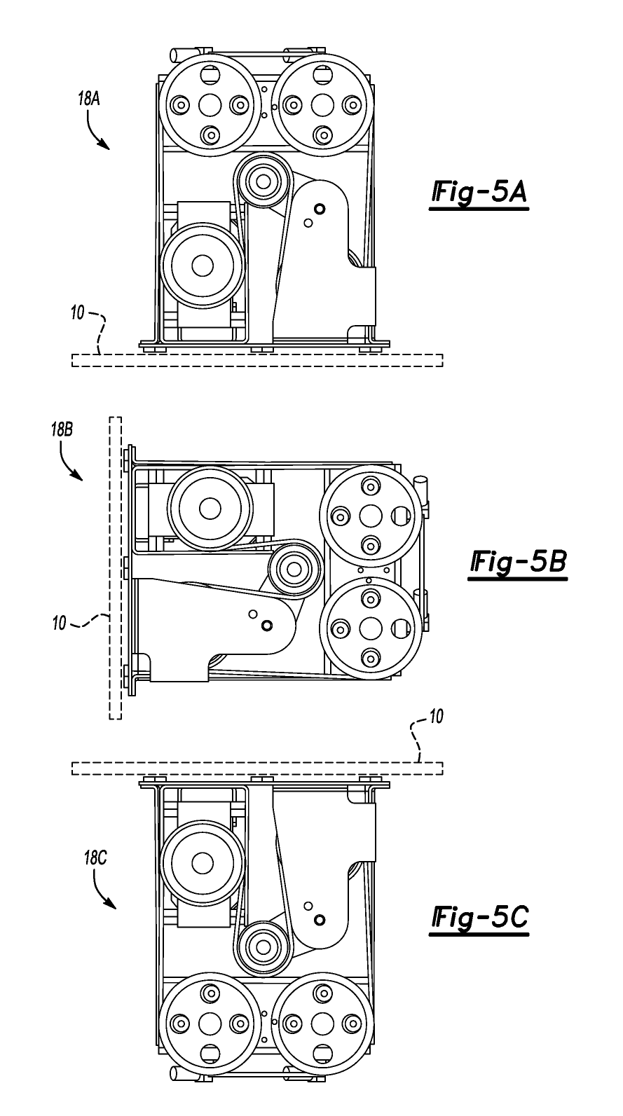

Referring to FIGS. 5A-C the accessory drive system 18A-C is shown in several different mounting configurations. FIG. 5A illustrates the accessory drive system 18A in a traditional bottom supported vertical mounting position on the vehicle 10. The weight of the accessory drive system 18A is supported by the vehicle 10. FIG. 5B illustrates the accessory drive system 18B in a side supported horizontal mounting position on the vehicle 10. Similar to the example above, the weight of the accessory drive system 18B is supported by the vehicle 10. Likewise, FIG. 5C illustrates the accessory drive system 18C in a top supported vertical mounting position on the vehicle 10. The weight of the accessory drive system 18C is supported by the vehicle 10. Therefore, as illustrated, the accessory drive system 18A-C may be mounted in various support positions. The accessory drive system 18 is independent of the main motor 12 for the vehicle 10 and therefore, may be located remotely from the motor 12 and a main engine compartment (not shown) of the vehicle 10. One skilled in the art would be able to determine the mounting location and orientation of the accessory drive system 18 based upon the particular vehicle 10 configurations which the accessory drive system 18 is used with.

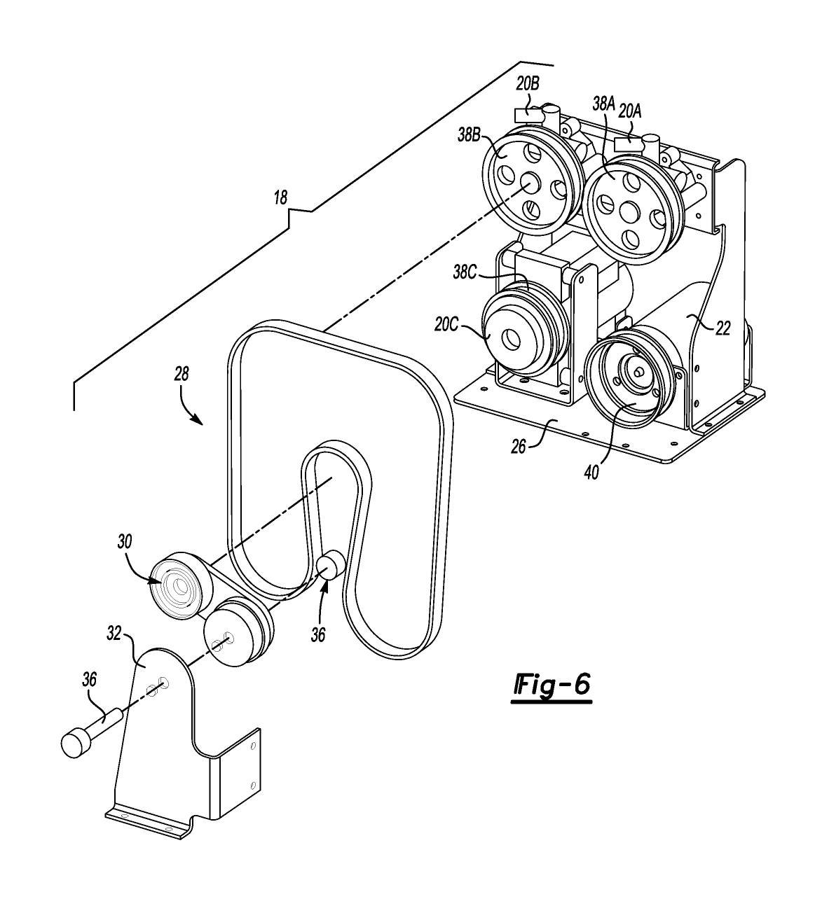

FIG. 6 is an exploded view of the accessory drive system 18. As mentioned previously, the belt tensioner bracket 32 may be removed for service of the accessory drive system 18. The belt tension bracket 32 is secured to the frame 26 with a plurality of fasteners (not shown). The belt tensioner 30 is secured to the belt tensioner bracket 32 with a fastener 36. Once the fastener 36 is released the belt tensioner bracket 32 and the belt tensioner 30 may be removed from the accessory drive system 18. Thereby, releasing the tension on the serpentine belt 28 which, may be removed for replacement or service. Likewise, the accessory drive components 20A-C and the motor 22 may now be individually removed or accessed for repair or replacement as well. As shown, releasing the belt tensioner 30 and the belt 28 allows servicing of the individual accessory drive components 20A-C and/or the motor 22 without requiring replacement of the entire accessory drive system 18. Additionally, depending upon the mounting location of the frame 26, within the vehicle 10 the individual accessory drive components 20A-C and/or the motor 22 may be accessed and serviced without requiring removal of the entire accessory drive system 18 from the vehicle 10. As long as the belt tensioner 30 can be removed a separate belt tensioner bracket 32 may not be necessary, based upon the configuration of the frame 26 for a specific accessory drive system 18.

The embodiment above discloses a vehicle 10 having an accessory drive system 18. However, multiple accessory drive systems 18 may be utilized by one vehicle 10 and be located in various locations and have various accessory components 20A-C associated therewith. One skilled in the art would be able to determine the number or accessory drive system 18, their placement within a particular vehicle 10 and the associated accessory components 20A-C most suited for a particular accessory drive system 18 and vehicle 10. Additionally, the size of the accessory drive system 18, including the accessory motor 22 and the accessory components 20A-C, may be scaled to efficiently accommodate either a small or large size vehicle.

In the embodiment shown, the accessory drive unit 18 is utilized to drive accessory components 20A-C for an automotive vehicle 10. However, the accessory drive unit 18 may be utilized in various other applications to drive accessory components 20A-C. For example, the accessory drive unit 18 may be utilized in the rail, naval or aerospace transportation industries where an electric motor is utilized as a main power source for the associated means of transportation.

While the best modes for carrying out the invention have been described in detail, those familiar with the art to which this invention relates will recognize various alternative designs and embodiments for practicing the invention within the scope of the appended claims.

1. An accessory drive system for a vehicle comprising:
an electric motor adapted for receiving power from a battery;
at least one accessory component for the vehicle;
a serpentine belt connecting the motor to the at least one accessory component such that the motor drives the at least one accessory component; and
an accessory frame for supporting the electric motor, and at least one accessory component for the vehicle.

2. The accessory drive system of claim 1, wherein the accessory drive system is a modular assembly.

3. The accessory drive system of claim 2, further comprising a belt tensioner, wherein the belt tensioner is removably secured to the accessory frame.

4. The accessory drive system of claim 1, further comprising a battery adapted for providing power to the electric motor.

5. The accessory drive system of claim 1, further comprising a controller adapted to control the electric motor.

6. The accessory drive system of claim 5, wherein the controller selectively powers the electric motor based upon a predetermined condition, and wherein the predetermined condition is based upon an operating condition of the at least one component.

7. The accessory drive system of claim 1, wherein the at least one accessory component is one of a power steering pump, an air conditioning compressor, and an emission control pump.

8. A vehicle comprising:
a first battery adapted to provide at least a portion of driving power for the vehicle; and
an accessory drive system including;
an accessory motor;
at least one accessory component;
a serpentine belt connecting the accessory motor to the at least one accessory component such that the accessory motor drives the at least one accessory component; and
a second battery configured to provide power to the accessory motor, wherein the second battery is electrically independent from the first battery.

9. The vehicle of claim 8, wherein the accessory drive system is a modular assembly.

10. The vehicle of claim 8, wherein the accessory drive system is located remotely from a powertrain of the vehicle.

11. The vehicle of claim 8, wherein the accessory drive system is operated separately from a powertrain of the vehicle.

12. The vehicle of claim 8, wherein the accessory drive system further comprises a controller adapted to control the accessory motor.

13. The accessory drive system of claim 12, wherein the controller selectively powers the accessory motor based upon a predetermined condition of the at least one component.

14. The vehicle of claim 8, wherein the accessory drive system further comprises an accessory frame for supporting the accessory motor, and at least one accessory component and wherein the accessory frame is removably secured to the vehicle.

15. The accessory drive system of claim 14, wherein the at least one accessory component is a plurality of accessory components and wherein each of the plurality of accessory components are mounted to the accessory frame and driven by the serpentine belt.

16. The accessory drive system of claim 8, wherein the at least one accessory component is one of a power steering pump, an air conditioning compressor, and an emission control pump.

17. A method driving an accessory component for a vehicle comprising:
providing at least a portion of the driving power for the vehicle with a first battery;
powering an electric motor with a second battery;
rotating a serpentine belt about a plurality of pulleys with the motor;
driving the at least one accessory component with the rotation of at least one of the plurality of pulleys such that the motor drives the at least one accessory component; and
mounting the at least one accessory component, and the electric motor to a frame to form a modular assembly which is supported by the vehicle.

18. The method of claim 17, further comprising adjusting a belt tensioner removably secured the frame to adjust a tension of the serpentine belt.

19. The method of claim 17, further comprising selectively powering a controller for the electric motor based upon a predetermined condition of the at least one component.

20. The method of claim 17, wherein driving the at least one accessory component further comprises driving one of a power steering pump, an air conditioning compressor, and an emission control pump.
